(19) United States
(12) Patent Application Publication
(10) Pub. No.: US 2023/0137766 A1
(43) Pub. Date: May 4, 2023

(54) Semiconductor Structures Having A Continuous Active Region

(71) Applicant: Taiwan Semiconductor Manufacturing Company, Ltd., Hsin-Chu (TW)

(72) Inventors: Ming-Yang Huang, Hsinchu (TW); Yung Feng Chang, Hsinchu City (TW); Tung-Heng Hsieh, Hsinchu County (TW); Bao-Ru Young, Hsinchu County (TW)

(21) Appl. No.: 17/876,741

(22) Filed: Jul. 29, 2022

Related U.S. Application Data
(60) Provisional application No. 63/274,145, filed on Nov. 1, 2021.

(51) Int. Cl. H01L 27/092; H01L 29/06; H01L 29/08; H01L 29/423; H01L 29/49; H01L 29/786; H01L 29/775; H01L 21/02; H01L 21/8238; H01L 29/66

(52) U.S. Cl. CPC H01L 27/0928; H01L 29/0673; H01L 29/0847; H01L 29/42392; H01L 29/4908; H01L 29/78696; H01L 29/775; H01L 21/02603; H01L 21/823807; H01L 21/823814; H01L 21/823842; H01L 21/823892; H01L 29/66545; H01L 29/66742; H01L 29/66439

(57) ABSTRACT

Semiconductor structures and methods are provided. A semiconductor structure according to an embodiment includes a substrate having an n well abutting a p well along a boundary. The semiconductor structure also includes a continuous active region over the n well and the p well, a plurality of gate structures over channel regions of the continuous active region, and one gate structure of the plurality of gate structures is disposed directly over the boundary. A portion of the channel region directly under the one gate structure is in direct contact with both an n-type source/drain feature over the p well and a p-type source/drain feature over the n well.

### CROSS-REFERENCE TO RELATED APPLICATIONS

This is a non-provisional application of and claims priority to U.S. Provisional Patent Application Ser. No. 63/274,145, filed on Nov. 1, 2021, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

Such scaling down has also increased the complexity of processing and manufacturing ICs. For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, or other nanostructures and for that reasons, an MBC transistor may also be referred to as a nanowire transistor or a nanosheet transistor. While existing technologies for fabricating multi-gate devices have been generally adequate for their intended purposes, they have not been entirely satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of an exemplary method for designing a layout, according to various aspects of the present disclosure.

FIG. 2 is a fragmentary layout of an exemplary semiconductor structure that includes a gate structure disposed directly over a boundary of an n well and a p well, according to various aspects of the present disclosure.

FIG. 3A illustrates an enlarged portion of the layout in FIG. 2, according to various aspects of the present disclosure.

FIG. 3B depicts an alternative embodiment of an enlarged portion of the layout, according to various aspects of the present disclosure.

FIG. 4 is a flow chart of an exemplary method for fabricating a semiconductor structure having the layout in FIG. 3A, according to various aspects of the present disclosure.

FIGS. 5-18 illustrate fragmentary cross-sectional views of a workpiece taken along line A-A′ as shown in FIG. 3A during a fabrication process according to the method of FIG. 4, according to various aspects of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

In circuit design, a standard cell is a block of transistors that is repeated according to a set of design rules across a design layout. A standard cell may be used for different functions. For example, a standard cell may be a static random access memory (SRAM) cell or a logic cell for logic operations. A standard cell may include one or more p-type transistors and one or more n-type transistors. The transistors may be planar transistors or multi-gate transistors, such as fin-type field effect transistors (FinFETs) or gate-all-around (GAA) transistors. To fabricate transistors on bulk substrates, n-type wells doped with n-type dopants and p-type wells doped with p-type dopants are formed in the bulk substrate and transistors of opposite conductivity types are formed over the respective n-type wells and p-type wells. Accordingly, a p-type transistor includes p-type source/drain features formed over an n-type well (n well) and an n-type transistor includes an n-type source/drain features formed over a p-type well (p well).

In conventional designs, elongated active regions, such as fins or vertical stacks of channel members, may be formed over the n well or the p well and doped with different types of dopants. Although n-type transistors and p-type transistors may be formed in the same substrate, the different doping types prevent them from being placed right next to each other. This is so because when a source/drain feature of the n-type transistors directly abuts a source/drain feature of a p-type transistor, it gives rise defects during the epitaxial growth of the source/drain feature of the n-type transistors and the source/drain feature of a p-type transistor and deteriorated performance. To isolate n-type transistors from p-type transistors, discontinuations of the active regions are introduced. Because the active regions are defined by a silicon-oxide containing isolation feature (such as a shallow trench isolation, or STI), the active regions may be referred to ODs and the discontinuations of the active regions may be referred to as OD breaks. In some embodiments, OD breaks are formed before the deposition of the isolation feature and the formation of the source/drain features. Source/drain feature(s) may refer to a source or a drain, individually or collectively dependent upon the context. Because the OD breaks are formed before the deposition of the isolation feature, the material for the deposition feature is also deposited in the OD breaks. Because the OD breaks are formed before the formation of the source/drain features that exert stress on the active region, the active regions adjacent to the OD breaks are exposed to different environment and may have different properties. The OD breaks therefore also bring about a form of LOD effect. The LOD effect is sometimes referred to as Length of Oxide Definition effect or Length Of Diffusion effect. Due to the LOD effect, transistors closer to the OD breaks (“edge transistors”) suffer from poorer performances than transistors further away from the diffusion-isolation edge (“center transistors”). Generally, edge transistors are treated as dummy transistors and not used for circuit functions, and center transistors are treated as operational transistors and used for circuit functions. In light of the foregoing, it can be seen that the edge transistors and OD breaks in the conventional designs can take up an undue amount of real estate in an IC chip.

The present disclosure provides semiconductor structures and methods of fabrication the same. An exemplary method includes providing a substrate having an n well abutting a p well along a boundary and forming a continuous active region (e.g., a semiconductor fin or a vertical stack of channel members) over the n well and the p well. The method also includes forming a number of gate structures over the continuous active region such that one gate structure of the number of gate structures is disposed directly over the boundary. The method also includes forming n-type source/drain features over the p well and forming p-type source/drain features over the n well. Therefore, a channel region under the gate structure is coupled to both an n-type source/drain feature over the p well and a p-type source/drain feature over the n well. Because the active region is a continuous active region extending along both n well and p well, the structure of the present disclosure does not require any OD break inserted between the n-type transistors and p-type transistors. In some embodiments, a number of transistors formed near that gate structure may be defined as dummy transistors to serve as a transition between the n-type transistors and p-type transistors and not used for circuit functions. Accordingly, the LOD effect may be avoided, and the area wasted by the edge transistors may be advantageously reduced or substantially eliminated, leading to improved design flexibility.

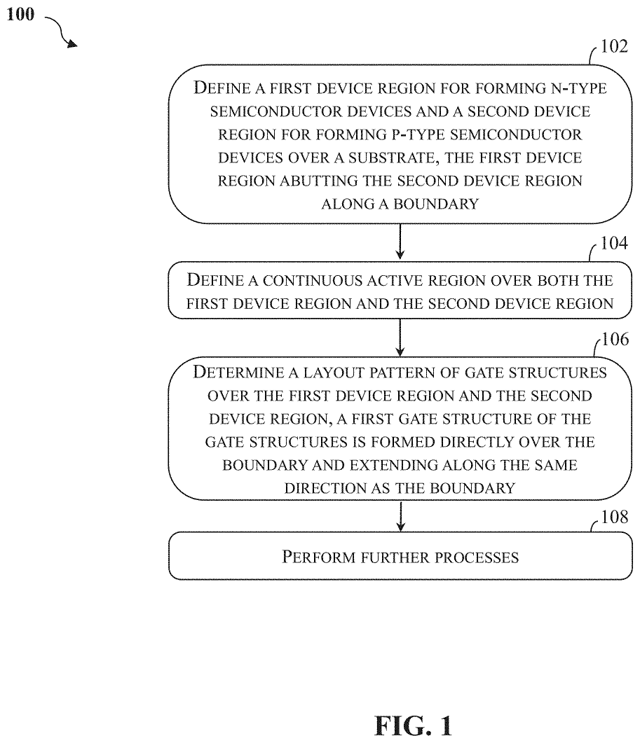

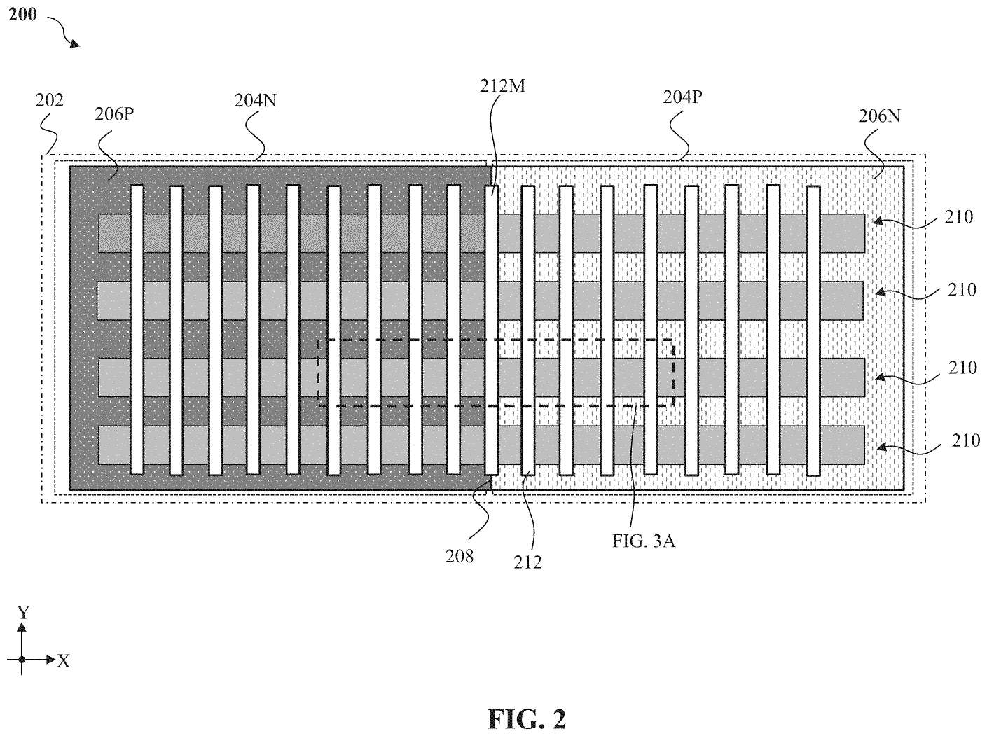

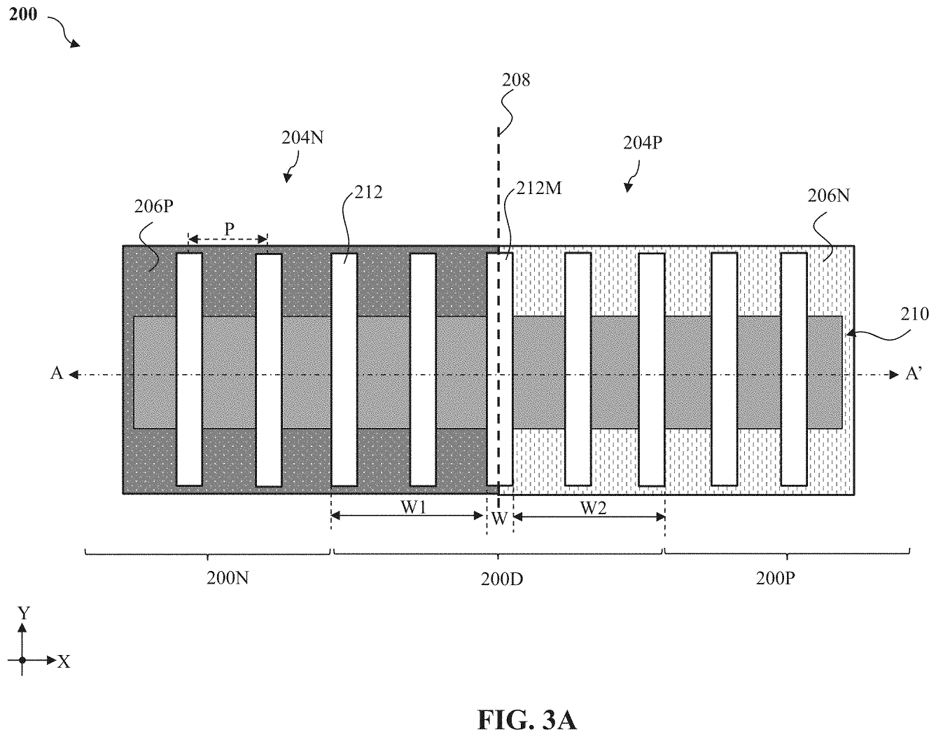

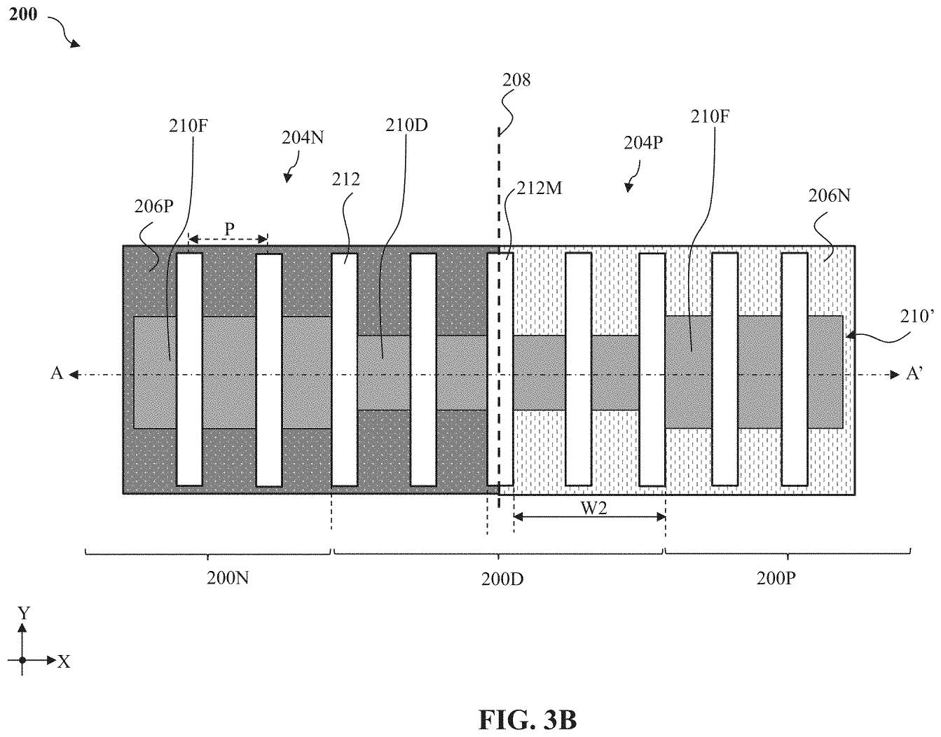

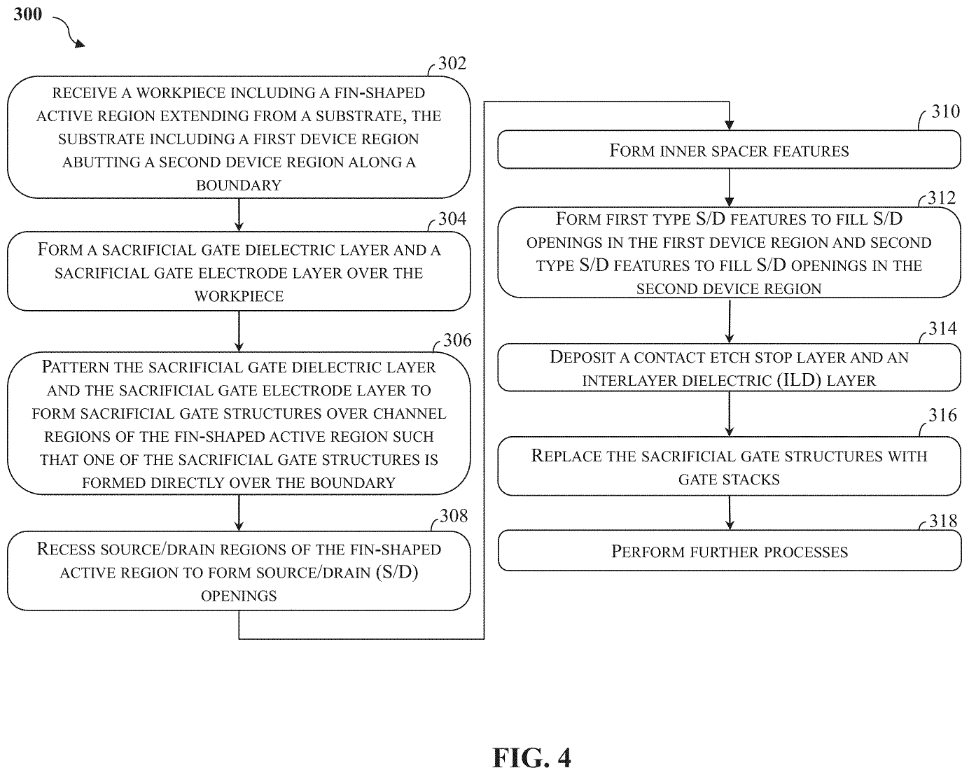

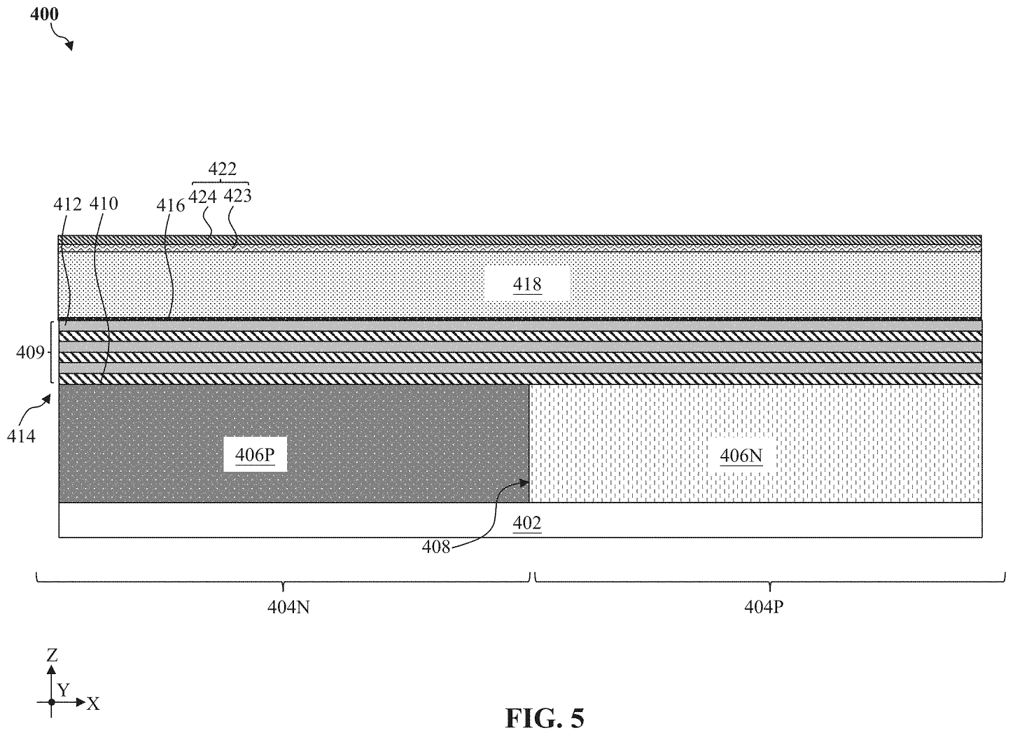

The various aspects of the present disclosure will now be described in more detail with reference to the figures. In that regard, FIG. 1 is a flowchart illustrating an exemplary method 100 of designing a layout 200, according to embodiments of the present disclosure. Method 100 is described below in conjunction with FIGS. 2 and 3A, which are a fragmentary layout view of an exemplary semiconductor structure, according to embodiments of method 100. FIG. 3B depicts an alternative embodiment of an enlarged portion of a layout. FIG. 4 is a flow chart of an exemplary method 300 for fabricating the semiconductor structure in FIG. 3A, according to various aspects of the present disclosure. Method 300 is described below in conjunction with FIGS. 5-18, which are fragmentary cross-sectional views of a workpiece 400 at different stages of fabrication according to embodiments of method 300. Method 300 may also be applied to fabricate the semiconductor structure in FIG. 3B, according to various aspects of the present disclosure.

Methods 100 and 300 are merely examples and are not intended to limit the present disclosure to what is explicitly illustrated therein. Additional steps may be provided before, during and after the methods 100 and 300, and some steps described can be replaced, eliminated, or moved around for additional embodiments of the methods. Not all steps are described herein in detail for reasons of simplicity. The layout of semiconductor structure 200 may be referred to as the layout 200 or semiconductor structure 200 as the context requires. Because the workpiece 400 will be fabricated into a semiconductor structure 400 upon conclusion of the fabrication processes, the workpiece 400 may be referred to as the semiconductor structure 400 as the context requires. For avoidance of doubts, the X, Y and Z directions in the figures are perpendicular to one another and are used consistently. Throughout the present disclosure, like reference numerals denote like features unless otherwise excepted.

Referring to FIGS. 1 and 2-3A, method 100 includes a block 102 where a first device region 204N for forming n-type semiconductor devices (e.g., transistors) and a second device region 204P for forming p-type semiconductor devices over a substrate 202 are defined. In the depicted embodiment, the substrate 202 includes silicon. In some embodiments, the substrate 202 may also include an insulating layer, such as a silicon oxide layer, to have a silicon-on-insulator (SOI) structure. Alternatively or additionally, the substrate 202 includes another elementary semiconductor, such as germanium; a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. In some implementations, the substrate 202 includes one or more group III-V materials, one or more group II-IV materials, or combinations thereof.

In embodiments represented in FIG. 2, both the first device region 204N and the second device region 204P are used to form standard cells. Each of the standard cells in the layout 200 may be a logic gate cell. In some embodiments, a logic gate cell includes an AND, OR, NAND, NOR, XOR, INV, AND-OR-Invert (AOI), OR-AND-Invert (OAI), MUX, Flip-flop, BUFF, Latch, delay, clock cells or the like. In some embodiments, a standard cell is a memory cell. In some embodiments, a memory cell includes a static random access memory (SRAM), a dynamic RAM (DRAM), a resistive RAM (RRAM), a magneto-resistive RAM (MRAM), read only memory (ROM), or the like. In some embodiments, a standard cell includes one or more active or passive elements. Examples of active elements include, but are not limited to, transistors and diodes. Examples of transistors include, but are not limited to, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), FinFETs, GAA devices, planar MOS transistors with raised source/drain, or the like. Examples of passive elements include, but are not limited to, capacitors, inductors, fuses, resistors, or the like.

In embodiments represented in FIG. 2, n-type transistors will be formed in the first device region 204N and p-type transistors will be formed in the second device region 204P, and the first device region 204N may be referred to as n-type device region 204N and the second device region 204P may be referred to as p-type device region 204P. In embodiments represented in FIG. 2, the n-type device region 204N includes a p-type well (p well) 206P and the p-type device region 204P includes an n-type well (n well) 206N. The n well 206N is doped with n-type dopants, such as phosphorus, arsenic, other n-type dopant, or combinations thereof. The p well 206P is doped with p-type dopants, such as boron, indium, other p-type dopant, or combinations thereof. An ion implantation process, a diffusion process, and/or other suitable doping process can be performed to form the various doped regions. In this depicted example, the n-type device region 204N abuts the p-type device region 204P along a boundary 208 (i.e., the interface 208 between the n-type device region 204N and the p-type device region 204P), and the n well 206N abuts the p well 206P along the boundary 208. In embodiments represented in FIG. 2, the boundary 208 extends lengthwise along the Y direction.

Referring to FIGS. 1 and 2, method 100 includes a block 104 where a region for forming an elongated continuous active region 210 over both the n-type device region 204N and the p-type device region 204P is defined. In this depicted example, the layout 200 includes four elongated and continuous active regions 210 over the substrate 202. It is understood that the number of continuous active regions 210 may be varied to accommodate different design requirements. Each of the active regions 210 may be a fin formed of silicon (or other semiconductor material) when the semiconductor structure includes a fin-type field effect transistor (FinFET) device or may include a vertical stack of semiconductor layers when the semiconductor structure includes a gate-all around (GAA) device. Each of the active regions 210 is elongated in shape and extends over the substrate 202 and extends across the boundary 208. In this depicted example, each of the active regions 210 extends lengthwise along the X direction. That is, each of the active regions 210 extends lengthwise along a direction that is substantially perpendicular to a lengthwise direction of the boundary 208. It is noted that, in some embodiments, the boundary 208 may extend lengthwise along the X direction and each of the plurality of active regions 210 may extend lengthwise along the Y direction.

Still referring to FIGS. 1 and 2, method 100 includes a block 106 where a layout pattern of gate structures 212 over the n-type device region 204N and the p-type device region 204P is determined such that a gate structure 212M of the number of gate structures 212 is disposed directly over the boundary 208. In some embodiments, a center line of the gate structure 212M aligns with the boundary 208. In some other implementations, a center line of the gate structure 212M may be offset from the boundary 208. To illustrate different further aspects of the present disclosure, a portion of the layout 200 in FIG. 2 is enlarged and illustrated in FIG. 3A. In this depicted example, each of the gate structures 212 extends lengthwise along the Y direction. That is, each of the gate structures 212 extends lengthwise along a direction that is substantially perpendicular to the lengthwise direction of the active regions 210 and substantially parallel to the lengthwise direction of the boundary 208. Each of the gate structures 212 is disposed over channel regions (not explicitly shown) of the active regions 210. The gate structures 212 also define source/drain regions of the active regions 210. That is, the channel regions of each of the active regions 210 is covered by the gate structures 212 and each channel region is disposed between two adjacent source/drain regions. In this depicted example, a gate pitch P is uniform across the layout 200. That is, a gate pitch for transistors in the n-type device region 204N is same to a gate pitch for transistors in the p-type device region 204P. In some implementations, the gate pitch for transistors in the n-type device region 204N may be different from the gate pitch for transistors in the p-type device region 204P.

To form n-type devices in the n-type device region 204N, n-type source/drain features may be formed in/over the source/drain regions of each of the active regions 210 over the p well 206P. To form p-type devices in the p-type device region 204P, p-type source/drain features may be formed in/over portion of the each of the active regions 210 over the p well 206P. By placing the gate structure 212M directly over the boundary 208, in the layout view, the p-type source/drain feature that is closest to the boundary 208 is separated from the n-type source/drain feature that is closest to the boundary 208 by the gate structure 210M. While the p-type source/drain feature is spaced apart from the n-type source/drain feature, they are aligned along the X direction as they are doped areas of the same active region to begin with. The p-type source/drain feature and the n-type source/drain feature are coupled to a same channel region disposed directly under the gate structure 212M. It can be seen that in the embodiments represented in FIGS. 2 and 3A, the workpiece 200 does not include any OD break inserted between the n-type device region 204N and the p-type device region 204P. This is evidenced by the fact that the active region 210 is a continuous active region. As described above, an OD break is a discontinuation in an active region formed before the formation of the isolation feature (such as STI). An OD break, if present, would be filled with the isolation feature. As FIGS. 2-3A illustrate no isolation feature that breaks up the active region 210, embodiments represented in FIGS. 2-3A do not include any OD break. Since the active region 210 is a continuous active region, the edge transistors (that exist in semiconductor structures where OD break exists) would not exist in semiconductor structure 200.

Considering the transition between n-type devices and p-type devices and characterization variations, a number of transistors near the boundary 208 may be defined as dummy transistors to serve as a transition between n-type operational transistors and p-type operational transistors and not used for circuit functions. As shown in FIG. 3A, the layout 200 includes an n-type operational device region 200N having n-type transistors used for circuit functions, a p-type operational device region 200P having p-type transistors used for circuit functions, and a dummy device region 200D having dummy transistors used for transition between the n-type operational device region 200N and the p-type operational device region 200P. The dummy device region 200D includes the boundary 208. In some implementations, the dummy transistors include both n-type transistors formed in the n-type device region 204N and p-type transistors formed in the p-type device region 204P. In some embodiments, the number of n-type dummy transistors may be equal to or different than the number of p-type dummy transistors. For example, the dummy device region 200D may include two n-type dummy transistors and two p-type dummy transistors. To increase the design flexibility (e.g., reduce the area for dummy devices and thus increase the area for operational devices) while ensuring the reliability of the operational devices, in embodiments represented in FIG. 3A, besides the gate structure 212M, the dummy device region 200D may span a width W1 along the −X direction in the n-type device region 204N and a width W2 along the X direction in the p-type device region 204P. That is, the dummy device region 200D may span a width equal to a sum of the width W1, width W2, and a width W of the gate structure 212M (i.e., W1+W2+W). In some embodiments, both a ratio of the width W1 to the gate pitch P (i.e., W1/P) and a ratio of the width W2 to the gate pitch P (i.e., W2/P) are no less than 2 to provide the workpiece 200 satisfactory device performances in both N-type operational device region 200N and P-type operational device region 200P while increasing the design flexibility. That is, dummy device region 200D includes at least five gate structures (including the gate structure 212M). The active region (including channel region and source/drain features) in the dummy device region 200D may be referred to as dummy active region, and the gate structures in the dummy device region 200D may be referred to as dummy gate structures.

Referring to FIGS. 1 and 2, method 100 includes a block 108 where further processes are performed. Such further processes may include, for example, performing DRC (design rule check) to verify whether the layout 200 is properly aligned with the design rules. Other suitable processes may be also performed to finish the layout design process.

In embodiments described above with reference to FIGS. 2-3A, the active region 210 has a uniform width along the X direction. To further reduce the undue amount of real estate employed by the dummy device region 200D in an IC chip, FIG. 3B depicts an embodiment where an active region 210′ of the workpiece 200 has an ununiform width along the X direction. In embodiments represented in FIG. 3B, the active region 210′ extends lengthwise along the X and across the boundary 208. More specifically, a portion 210D of the active region 210′ in the dummy device region 200D has a width smaller than a width of a portion 210F of the active region 210′ in the n-type operational device region 200N or the p-type operational device region 200P. Although the width of the active region 210′ is not uniform along the X direction, it can be seen that the workpiece 200 shown in FIG. 3B does not include any OD break inserted between the n-type device region 204N and the p-type device region 204P.

FIG. 4 illustrates a flow chart of an exemplary method 300 for fabricating the semiconductor structure 200 in FIG. 3A, according to various aspects of the present disclosure. Referring to FIGS. 4 and 5, method 300 includes a block 302 where a workpiece 400 is provided. The workpiece 400 includes a substrate 402. The substrate 402 may be in a way similar to the substrate 202. The workpiece 400 includes a first device region 404N for forming first type transistors (e.g., n-type transistors) and a second device region 404P for forming second type transistors (e.g., p-type transistors). The substrate 402 includes an n-type well (n well) 406N in the second device region 404P and a p-type well (p well) 406P in the first device region 404N. The n well 406N may be in a way similar to the n well 206N. The p well 406P may be in a way similar to the p well 206P. The n well 406N abuts the p well 406P along a boundary 408. The boundary 408 extends lengthwise along the Y direction. P-type transistors would be formed in and over the n well 406N, and n-type transistors would be formed in and over the p well 406P.

As shown in FIG. 5, the workpiece 400 also includes a stack 409 disposed over the substrate 402. The stack 409 extends lengthwise along the X direction and is formed over both the n well 406N and the p well 406P and extends across the boundary 408. The stack 409 includes a number of sacrificial layers 410 and a number of channel layers 412 interleaved by the number of sacrificial layers 410. The channel layers 412 and the sacrificial layers 410 may have different semiconductor compositions. In some implementations, the channel layers 412 are formed of silicon (Si) and the sacrificial layers 410 are formed of silicon germanium (SiGe). In some embodiments, the sacrificial layers 410 and channel layers 412 may be deposited using an epitaxial process. Suitable epitaxial processes include vapor-phase epitaxy (VPE), ultra-high vacuum chemical vapor deposition (UHV-CVD), molecular beam epitaxy (MBE), and/or other suitable processes. As shown in FIG. 5, the sacrificial layers 410 and the channel layers 412 are deposited alternatingly, one-after-another, to form the stack 409. It is noted that three layers of the sacrificial layers 410 and three layers of the channel layers 412 are alternately and vertically arranged as illustrated in FIG. 5, which are for illustrative purposes only and not intended to be limiting beyond what is specifically recited in the claims. It is understood that any number of sacrificial layers and channel layers can be formed in the stack 409. The number of layers depends on the desired number of channels members for the structure 400. In some embodiments, the number of the channel layers 412 is between 2 and 10.

The stack 409 and a portion of the substrate 402 are patterned to form a fin-shaped active region 414 extending vertically along the Z direction from the substrate 402 and extending lengthwise along the X direction. In some embodiments, the active region 414 may be in a way similar to the active region 210. The fin-shaped active region 414 includes a base portion formed from the substrate 402 and a stack portion formed from the stack 409. The fin-shaped active region 414 may be patterned using suitable processes including double-patterning or multi-patterning processes.

Operations in block 302 may also include formation of an isolation feature adjacent and around the base portion of the fin-shaped active region 414. The isolation feature is disposed between the fin-shaped active region 414 and another fin-shaped active region. The isolation feature may also be referred to as a shallow trench isolation (STI) feature. In some embodiments, the isolation feature may include silicon oxide, silicon nitride, silicon oxynitride, fluorine-doped silicate glass (FSG), a low-k dielectric, combinations thereof, and/or other suitable materials. The formation of the isolation feature may involve multiple processes such as deposition and etching. As shown in FIG. 5, the fin-shaped active region 414 extends continuously along the X direction and across the boundary 408, and the workpiece 400 doesn't include a STI feature or other types of isolation structure disposed in or over the substrate 402 to cut the fin-shaped active region 414 into pieces to isolate to-be-formed N-type transistors and P-type transistors.

Still Referring to FIGS. 4 and 5, method 300 includes a block 304 where a sacrificial gate dielectric layer 416 and a sacrificial gate electrode layer 418 are sequentially deposited over the workpiece 400, including over the fin-shaped active region 414. In some embodiments, the sacrificial gate dielectric layer 416 may include silicon oxide and the sacrificial gate electrode layer 418 may include polycrystalline silicon (poly silicon). In the present embodiments, a gate top hard mask layer 422 is deposited over the sacrificial gate electrode layer 418. The gate top hard mask layer 422 may include multiple layers or a single layer. In this depicted embodiment, the gate top hard mask layer 422 includes a first hard mask 423 and a second hard mask 424 over the first hard mask 423. The first hard mask 423 may include silicon oxide and the second hard mask 424 may include silicon nitride. The sacrificial gate dielectric layer 416, the sacrificial gate electrode layer 418, and the gate top hard mask layer 422 may be formed by suitable deposition processes. Exemplary deposition processes include low-pressure CVD (LPCVD), CVD, plasma-enhanced CVD (PECVD), PVD, atomic layer deposition (ALD), thermal oxidation, e-beam evaporation, or other suitable deposition techniques, or combinations thereof.

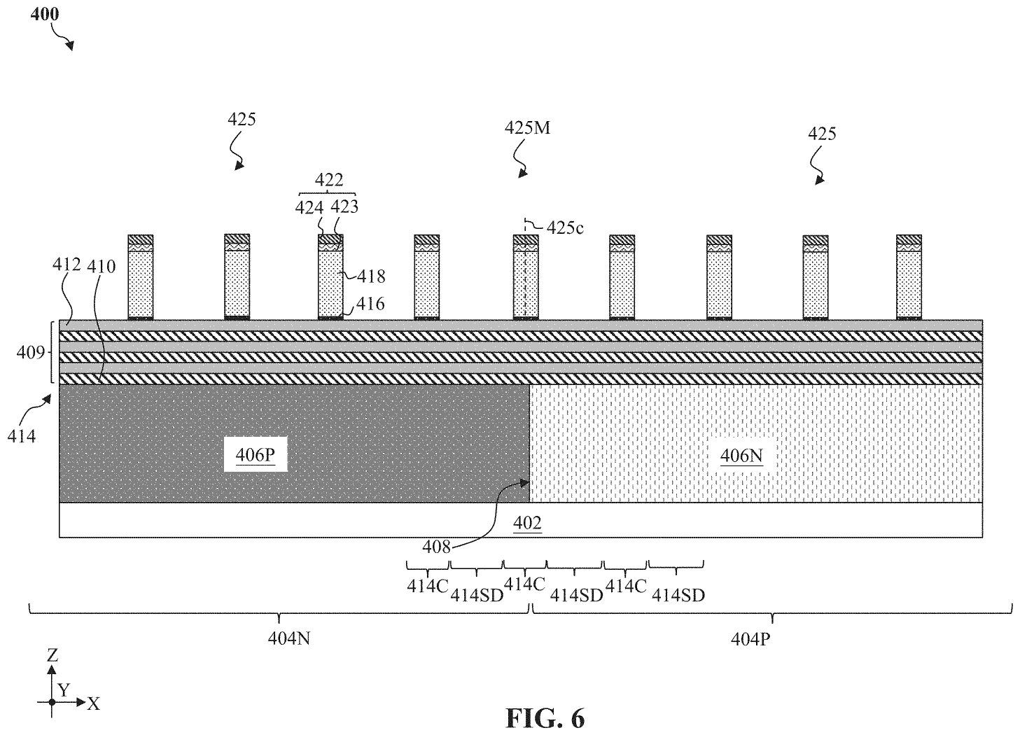

Referring to FIGS. 4 and 6, method 300 includes a block 306 where the sacrificial gate dielectric layer 416, the sacrificial gate electrode layer 418, and the gate top hard mask layer 422 are patterned to form a number of sacrificial gate structures 425 over the workpiece 400 such that one sacrificial gate structure 425M of the number of sacrificial gate structures 425 is disposed directly over the boundary 408. As shown in FIG. 5, the sacrificial gate structures 425 (including the sacrificial gate structure 425M) are formed over the fin-shaped active region 414. In some embodiments, a gate replacement process (or gate-last process) is adopted where the sacrificial gate structure 425 serves as a placeholder for a gate stack. Other processes and configuration are possible. The sacrificial gate structures 425 each extend lengthwise along the Y direction to wrap over channel regions 414C of the fin-shaped active region 414. In embodiments represented in FIG. 6, the center line 425c of the sacrificial gate structure 425M substantially aligns with the boundary 408. In some other embodiments, there may be an offset between the center line 425c and the boundary 408. In embodiments represented in FIG. 6, the sacrificial gate structures 425 include a uniform gate pitch P in the workpiece 400. In some other implementations, the gate pitch of sacrificial gate structures 425 in the first device region 404N may be different from the gate pitch of sacrificial gate structures 425 in the second device region 404P to fulfill different functions.

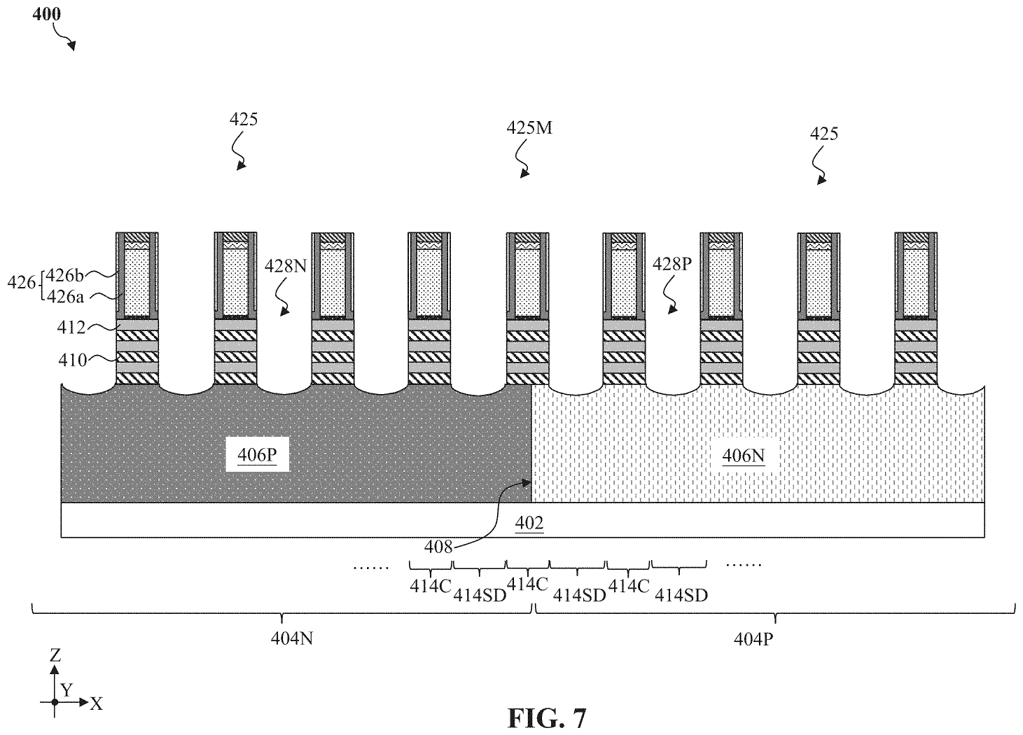

Referring to FIG. 7, after the formation of the sacrificial gate structures 425, a gate spacer layer 426 is formed over sidewalls of the sacrificial gate structures 425. In some embodiments, the formation of the gate spacer layer 426 includes conformal deposition of one or more dielectric layers over the workpiece 400 and etch-back of the gate spacer layer 426 from top-facing surfaces of the workpiece 400 by an anisotropic etching process. In embodiments represented in FIG. 7, the gate spacer layer 426 includes a first spacer layer 426a in direct contact with the sacrificial gate structures 425 and a second spacer layer 426b on the first spacer layer 426a. The second spacer layer 426b is spaced apart from the sacrificial gate structure 425 by the first spacer layer 426a. In an exemplary process, the first spacer layer 426a and the second spacer layer 426b are deposited using CVD, SACVD, or ALD. The first spacer layer 426a and the second spacer layer 426b may include silicon oxide, silicon nitride, silicon carbide, silicon oxynitride, silicon carbonitride, silicon oxycarbide, silicon oxycarbonitride, and/or combinations thereof. As shown in FIG. 7, the fin-shaped active region 414 includes channel regions 414C underlying the sacrificial gate structures 425 and the gate spacer layer 426, and source/drain regions 414SD that are not vertically overlapped by the sacrificial gate structures 425 or the gate spacer layer 426. The channel region 414C is disposed between two source/drain regions 414SD.

Referring to FIGS. 4 and 7, method 300 includes a block 308 where source/drain regions 414SD of the fin-shaped active region 414 are recessed to form source/drain openings 428N in the first device region 404N and source/drain openings 428P in the second device region 404P. In embodiments represented in FIG. 7, the source/drain regions 414SD of the fin-shaped active region 414, which are not covered by the gate top hard mask layer 422 (shown in FIG. 6) or the gate spacer layer 426, are recessed to form the source/drain openings 428N/428P. The etching process may be a dry etching process or a suitable etching process. The dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As shown in FIG. 7, sidewalls of the sacrificial layers 410 and the channel layers 412 are exposed in the source/drain openings 428N/428P.

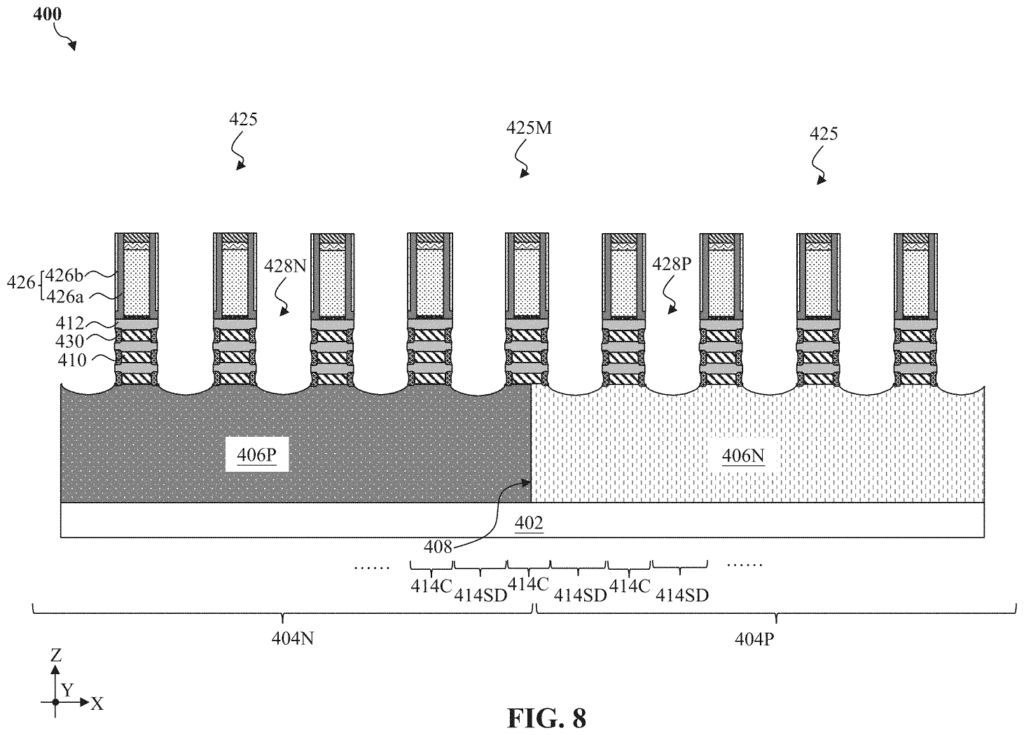

Referring to FIGS. 4 and 8, method 300 includes a block 310 where inner spacer features 430 are formed. The sacrificial layers 410 exposed in the source/drain openings 428N/428P are selectively and partially recessed to form inner spacer recesses (filled by inner spacer features 430). In some embodiments, the selective recess may include performing a selective isotropic etching process (e.g., a selective dry etching process or a selective wet etching process), and the extent at which the sacrificial layers 410 and the channel layers 412 are recessed is controlled by duration of the etching process. The selective dry etching process may include use of one or more fluorine-based etchants, such as fluorine gas or hydrofluorocarbons. The selective wet etching process may include a hydro fluoride (HF) or NH₄OH etchant. After forming the inner spacer recesses, a spacer material layer may be deposited over the workpiece 400 to fill the inner spacer recesses using ALD and may include silicon oxide, silicon nitride, silicon oxycarbide, silicon oxycarbonitride, silicon carbonitride, metal nitride, or a suitable dielectric material. The spacer material layer may be etched back to remove recess spacer material layer to form the inner spacer features 430.

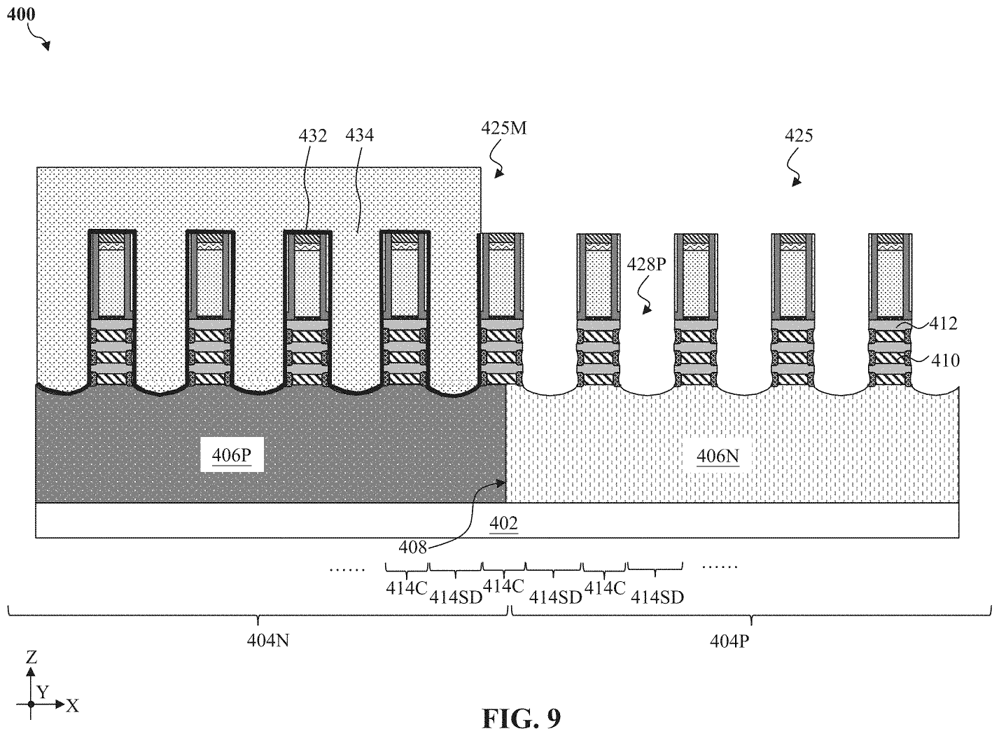

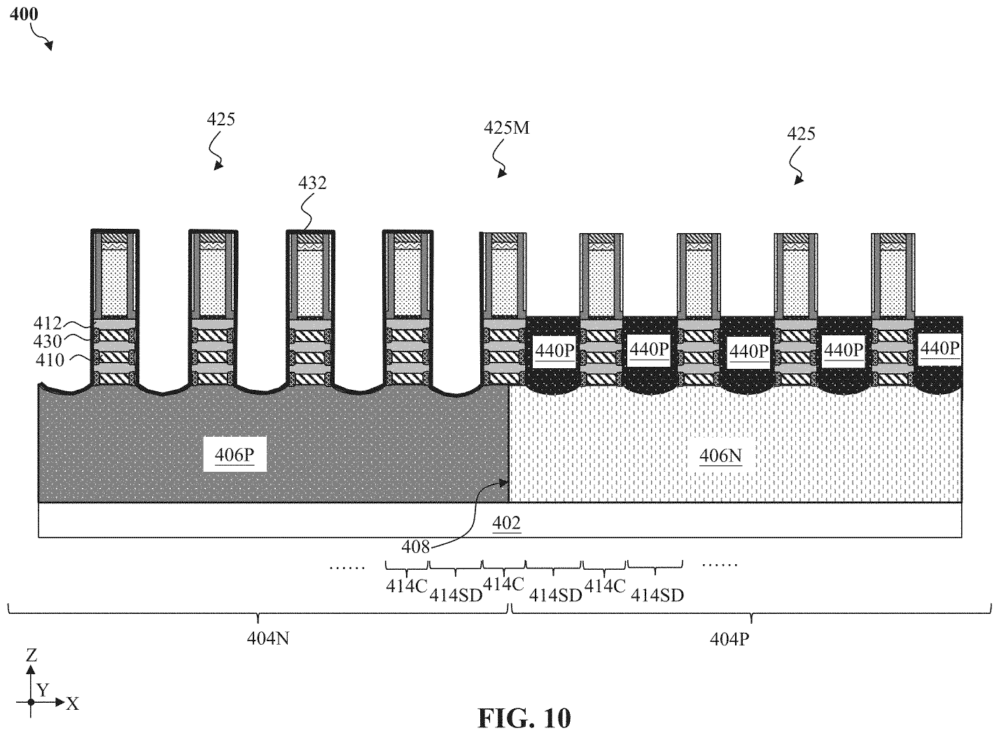

Referring to FIG. 4 and FIGS. 9, 10, 11, method 300 includes a block 312 where p-type epitaxial source/drain features 440P are formed in the source/drain openings 428P and n-type epitaxial source/drain features 440N are formed in the source/drain openings 428N. In this depicted example, the p-type epitaxial source/drain features 440P are formed before forming the n-type epitaxial source/drain features 440N. It is understood that the n-type epitaxial source/drain features 440N may be formed before forming the p-type epitaxial source/drain features 440P. To form the p-type epitaxial source/drain features 440P in the source/drain openings 428P, a pattern film 432 is deposited over the first device region 404N and the second device region 404P. In some embodiments, the pattern film 432 may include silicon nitride or silicon carbonitride. This arrangement allows the pattern film 432 to be selectively removed later on without substantially damaging the inner spacer features 430. In some implementations, the pattern film 432 may be deposited using CVD, PECVD, LPCVD, ALD or other suitable method. In some embodiments shown in FIG. 9, photolithography techniques are used to pattern the pattern film 432. A photoresist layer is deposited over the workpiece 400 by, for example, spin-on coating. The photoresist layer is then exposed to a patterned radiation, post-baked, and developed to form a patterned photoresist layer 434 that exposes the second device region 404P while covering the first device region 404N. As shown in FIG. 10, the exposed photoresist layer 434 over the first device region 404N may then be removed by a suitable etching process, and the patterned pattern film 432 functions as a mask to cover the first device region 404N. In embodiments represented in FIG. 9, the patterned pattern film 432 aligns with the gate spacer layer 426 of the sacrificial gate structure 425M over the first device region 404N to cover all the source/drain openings 428N. In some embodiments, the patterned pattern film 432 may cover a portion of the sacrificial gate structure 425M. That is, the patterned pattern film 432 is formed to cover all the source/drain openings 428N while exposing the source/drain openings 428P.

Referring to FIG. 10, after forming the patterned pattern film 432 in the first device region 404N, the p-type epitaxial source/drain features 440P are formed over source/drain openings 428P in the second device region 404P. Suitable epitaxial processes for forming the p-type epitaxial source/drain features 440P include CVD deposition techniques (e.g., vapor-phase epitaxy (VPE) and/or ultra-high vacuum CVD (UHV-CVD)), molecular beam epitaxy (MBE), and/or other suitable processes. The epitaxial growth process may use gaseous and/or liquid precursors, which interact with the composition of the substrate 402 and/or the channel layers 412. The p-type epitaxial source/drain features 440P may be in direct contact with the substrate 402, the channel layers 412 and the sacrificial layers 410. In various embodiments, the p-type epitaxial source/drain features 440P may include Si, Ge, AlGaAs, SiGe, boron-doped SiGe (SiGeB), or other suitable material. The p-type epitaxial source/drain features 440P may be in-situ doped during the epitaxial process by introducing doping species including p-type dopants, such as boron or BF₂, and/or other suitable dopants including combinations thereof. In some implementations, an implantation process may be performed to dope the p-type epitaxial source/drain features 440P. In an exemplary embodiment, the p-type epitaxial source/drain features 440P in the second device region 404P include SiGeB. After forming the p-type epitaxial source/drain features 440P, the patterned pattern film 432 covering the first device region 404N may be removed. Another patterned pattern film (not explicitly shown) may be then formed to cover the second device region 404P while exposing the source/drain openings 428N in the first device region 404N.

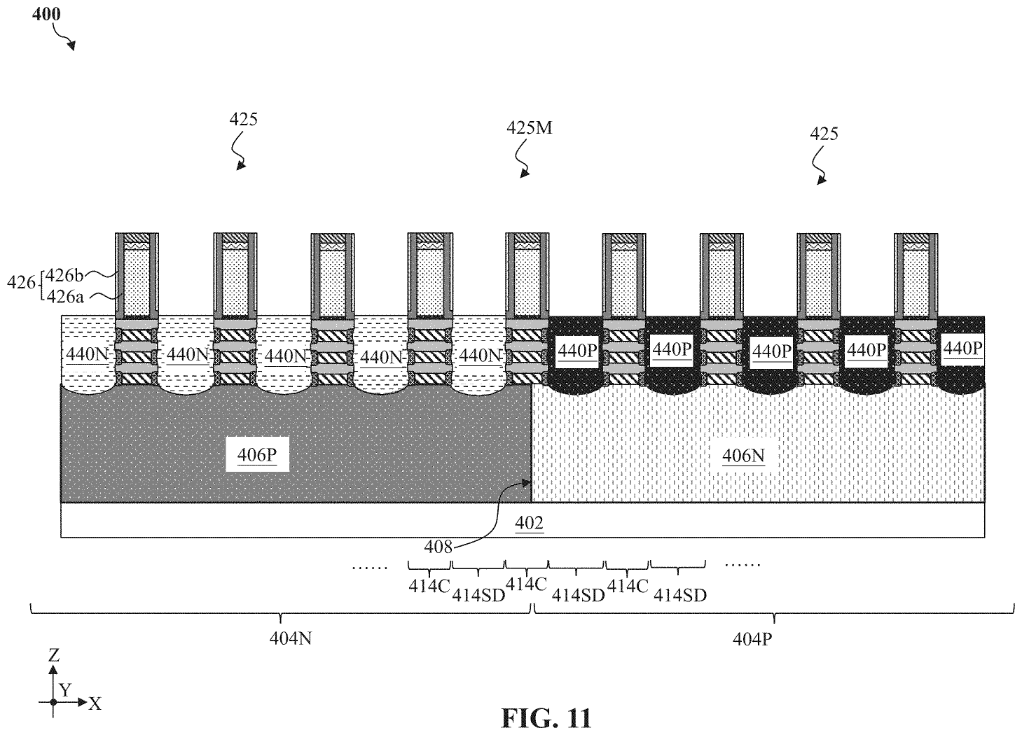

Referring to FIG. 11, with another patterned pattern film covering the second device region 404P, n-type epitaxial source/drain features 440N are formed in and/or over the source/drain openings 428N in the first device region 404N. Suitable epitaxial processes for forming n-type epitaxial source/drain features 440N may be in a way similar to the epitaxial processes for forming P-type epitaxial source/drain features 440P. In various embodiments, the n-type epitaxial source/drain features 440N may include Si, GaAs, GaAsP, SiP, or other suitable material. The n-type epitaxial source/drain features 440N may be in-situ doped during the epitaxial process by introducing doping species including n-type dopants, such as phosphorus or arsenic; and/or other suitable dopants including combinations thereof. In some implementations, an implantation process may be performed to dope the n-type epitaxial source/drain features 440N. In an exemplary embodiment, the n-type epitaxial source/drain features 440N in the first device region 404N include SiP. After forming the n-type epitaxial source/drain features 440N, the patterned pattern film covering the second device region 404P may be removed.

In embodiments represented in FIG. 11, the n-type epitaxial source/drain features 440N are formed over the p well 406P in the first device region 404N, the p-type epitaxial source/drain features 440P are formed over the n well 406N in the second device region 404P. The channel region 414C directly under the sacrificial gate structure 425M is in direct contact with both the n-type epitaxial source/drain feature 440N closest to the boundary 408 and the p-type epitaxial source/drain feature 440P closest to the boundary 408. That is, after forming the n-type epitaxial source/drain features 440N and p-type epitaxial source/drain features 440P, the active region (including channel regions and source/drain features) of the workpiece 400 shown in FIG. 11 is still continuous.

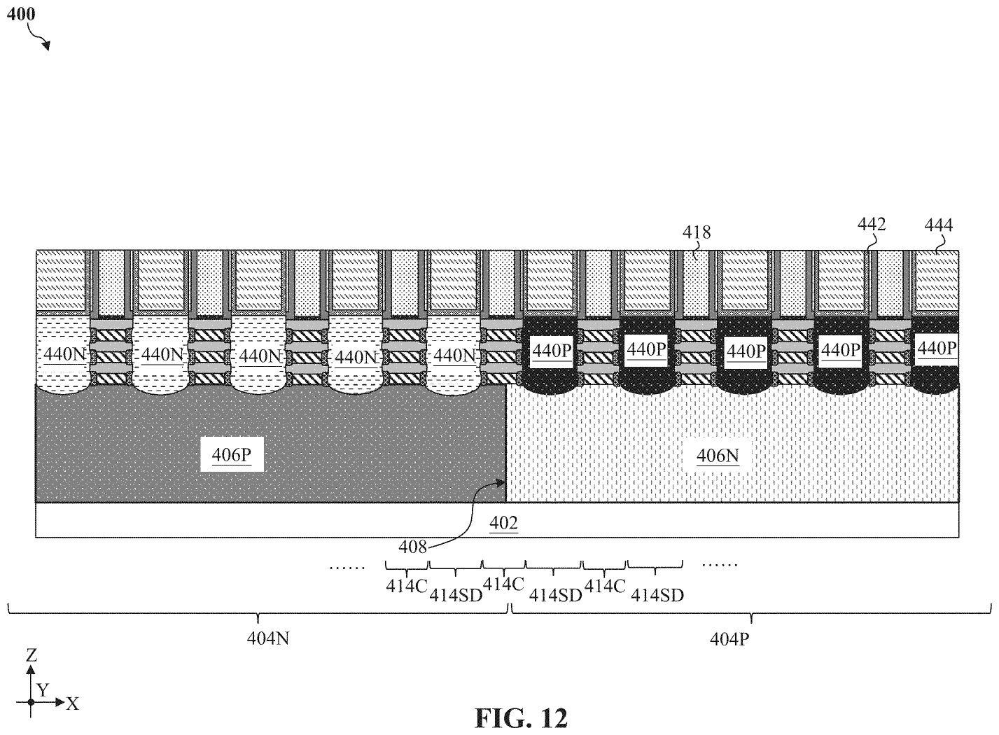

Referring to FIGS. 4 and 12, method 300 includes a block 314 where a contact etch stop layer (CESL) 442 and an interlayer dielectric (ILD) layer 444 are deposited over the workpiece 400. The CESL 442 may include silicon nitride, silicon oxide, silicon oxynitride, and/or other materials known in the art and may be formed by ALD, plasma-enhanced chemical vapor deposition (PECVD) process and/or other suitable deposition or oxidation processes. As shown in FIG. 12, the CESL 442 may be deposited on top surfaces of the source/drain features 440N/440P and along sidewalls of the gate spacer layer 426. Although the CESL 442 is also deposited over the top surfaces of the gate spacer layer 426 and the gate top hard mask layer 422, FIG. 12 only illustrates a cross-sectional view of the workpiece 400 after the gate top hard mask layer 422 is removed.

Still referring to FIG. 12, block 314 also includes depositing of the ILD layer 444 over the CESL 442. In some embodiments, the ILD layer 444 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 444 may be deposited by a PECVD process or other suitable deposition technique. A planarization process, such a chemical mechanical polishing (CMP) process may be performed to remove excess materials and the gate top hard mask layer 422 to expose top surfaces of each sacrificial gate electrodes 418.

Referring to FIG. 4 and FIGS. 12-15, method 300 includes a block 316 where the sacrificial gate structures 425 (including the sacrificial gate structure 425M) are replaced by gate stacks. The replacement includes performing one or more etching processes to remove the sacrificial gate structures 425 in the first device region 404N and the second device region 404P (including the sacrificial gate structure 425M), resulting gate trenches (not explicitly shown). The etching process may be selective to the material in the sacrificial gate structures 425. For example, the removal of the sacrificial gate structures 425 may be performed using as a selective wet etching, a selective dry etching, or a combination thereof. After the removal of the sacrificial gate structures 425, sidewalls of the channel layers 412 and sacrificial layers 410 in the channel regions 414C are exposed in the gate trenches. The sacrificial layers 410 in the channel regions 414C are selectively removed to release the channel layers 412 as channel members 412. The selective removal of the sacrificial layers 410 forms a number of openings (not explicitly shown) in the channel region 414C. The selective removal of the sacrificial layers 410 may be implemented by a selective dry etching, a selective wet etching, or other selective etching processes. In one embodiment, the selective removal of the sacrificial layers 410 is performed using a selective wet etch, such as an APM etch (e.g., ammonia hydroxide-hydrogen peroxide-water mixture).

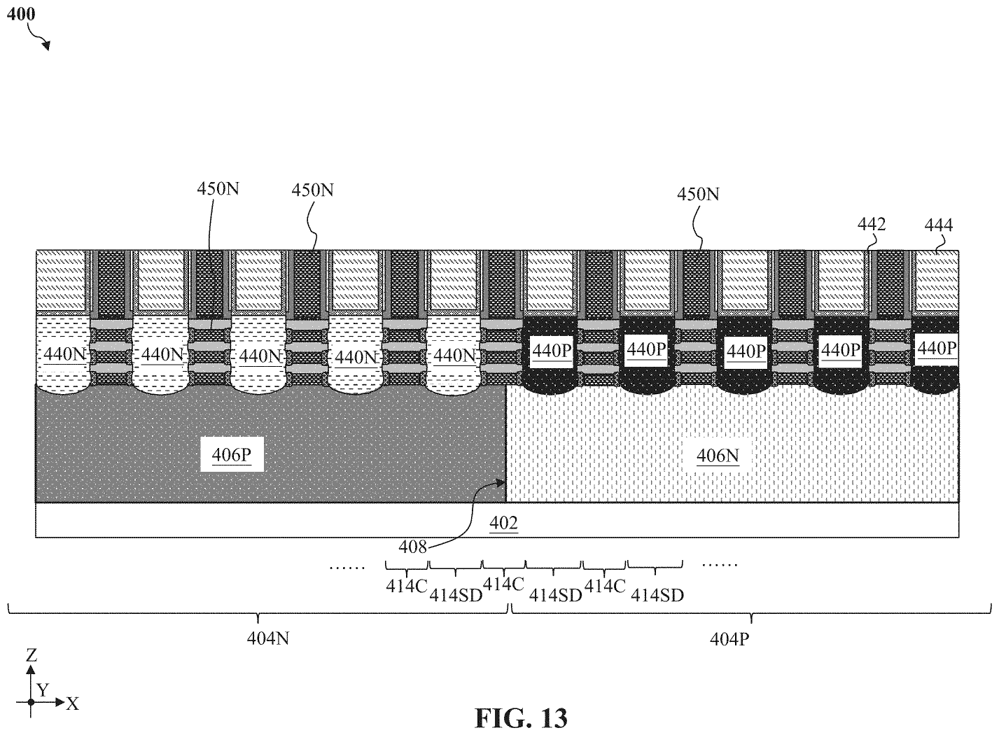

As shown in FIG. 13, gate stacks 450N are formed over and around the channel members 412, including into the openings in the channel region 414C and the gate trenches in the first and second device regions 404N-404P and over the boundary 408. Although not explicitly shown, each of the gate stacks 450N includes a gate dielectric layer and a gate electrode formed over the gate dielectric layer. In an exemplary process, a gate dielectric layer is deposited over the workpiece 400, the gate electrode is deposited over the gate dielectric layer, and a planarization process is followed to remove excess materials. In some embodiments, the gate dielectric layer may include an interfacial layer and a high-k dielectric layer. High-K gate dielectrics, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be deposited using chemical oxidation, thermal oxidation, ALD, CVD, and/or other suitable method. The high-K dielectric layer may include hafnium oxide, titanium oxide, hafnium zirconium oxide, tantalum oxide, hafnium silicon oxide, zirconium silicon oxide, lanthanum oxide, aluminum oxide, zirconium oxide, yttrium oxide, SrTiO₃ (STO), BaTiO₃ (BTO), Ba₇rO, hafnium lanthanum oxide, lanthanum silicon oxide, aluminum silicon oxide, hafnium tantalum oxide, hafnium titanium oxide, (Ba,Sr)TiO₃ (BST), silicon nitride, silicon oxynitride, combinations thereof, or other suitable material. The high-K dielectric layer may be formed by ALD, physical vapor deposition (PVD), CVD, oxidation, and/or other suitable methods. The gate electrode of the gate stack 450N may include a single layer or alternatively a multi-layer structure, such as various combinations of a metal layer with a selected work function to enhance the device performance (work function metal layer), a liner layer, a wetting layer, an adhesion layer, a metal alloy or a metal silicide. In various embodiments, the gate electrode may be formed by ALD, PVD, CVD, e-beam evaporation, or other suitable process. Each of the gate stacks 450N may include an n-type work function metal layer. The n-type work function metal layer may include Ti, Al, Ag, Mn, Zr, TiAl, TiAlC, TaC, TaCN, TaSiN, TaAl, TaAlC, TiAlN, other n-type work function material, or combinations thereof. The gate stack that is formed directly over the boundary 408 may be referred to as gate stack 450M.

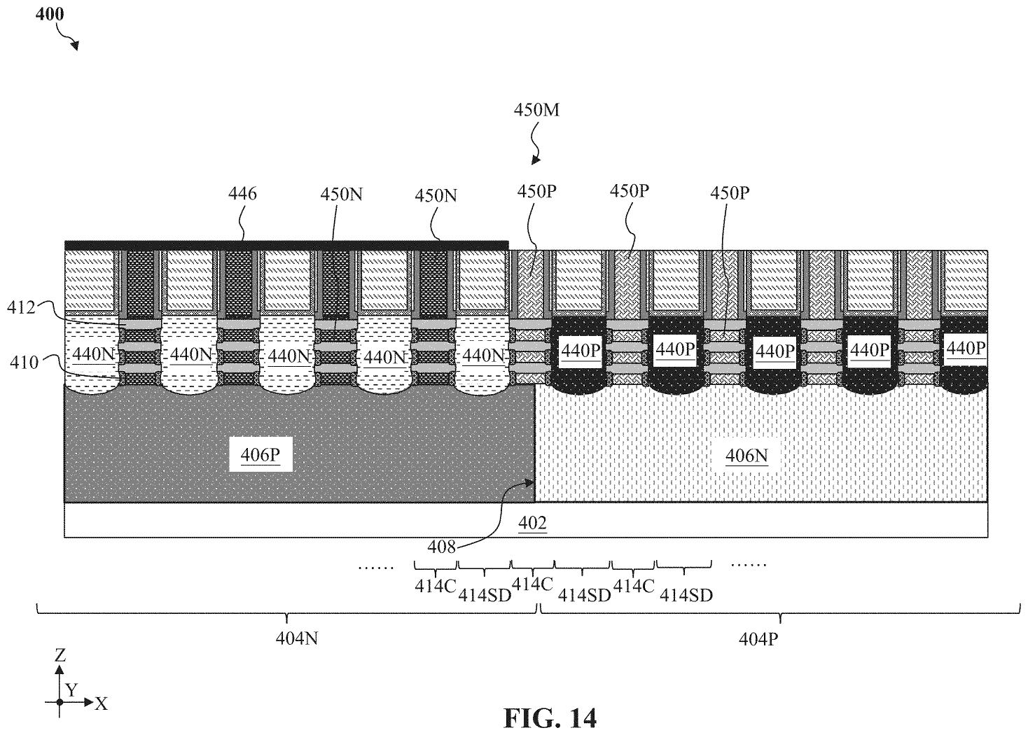

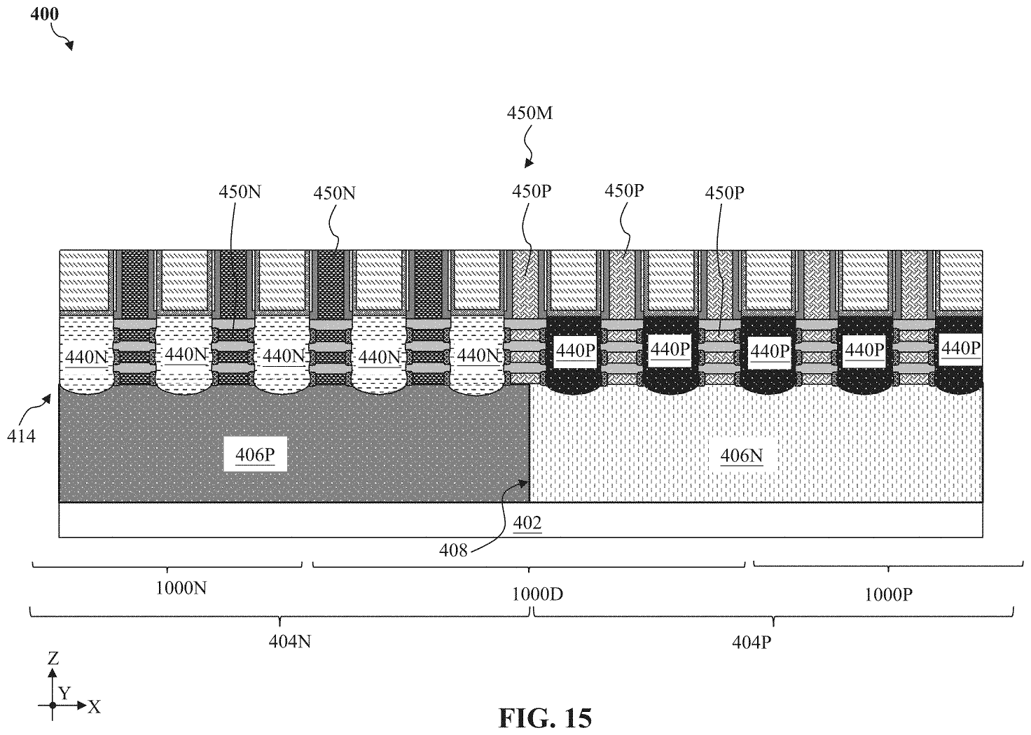

Referring now to FIGS. 14-15, after replacing all the sacrificial gate structures 425 with gate stacks 450N, the gate stacks 450N formed over the second device region 404P are replaced with gate stacks 450P. For example, the n-type work function metal layer formed over the second device region 404P may be replaced with p-type function metal layer such as TiN, TaN, Ru, Mo, Al, WN, ZrSi₂, MoSi₂, TaSi₂, NiSi₂, WCN, other p-type work function material, or combinations thereof. A patterned pattern film 446 may be formed over the first device region 404N. The formation and/or materials of the patterned pattern film 446 may be in a way similar to the patterned pattern film 432. In embodiments represented in FIG. 14, the patterned pattern film 446 covers the gate stacks 450N in the first device region 404N while exposing the gate stacks 450N in the second device region 404P and the gate stack 450M. In some other implementations, the patterned pattern film 446 may cover the gate stacks 450N in the first device region 404N and the gate stack 450M while exposing gate stacks 450N in the second device region 404P. As shown in FIG. 15, the patterned pattern film 446 may be selectively removed after forming the stacks 450P over the second device region 404P.

In embodiments represented in FIGS. 14-15, the gate stack 450M, formed over the boundary 408, has the same structure and composition as those of the gate stack 450P. However, it is noted that, in some other embodiments, the gate stack 450M may have the same structure and composition as those of the gate stack 450N. The gate stack 450M is disposed between the n-type epitaxial source/drain feature 440N and the p-type epitaxial source/drain features 440P. The n-type transistors formed over the first device region 404N transitions to p-type transistors formed over the second device region 404P via the gate stack 450 formed directly over the boundary 408 without changing the continuity of the active region 414.

As described above, due to the transition between n-type transistors and p-type transistors formed over a same active region 414, characterizations of the n-type transistors and p-type transistors in the workpiece 400 may vary as a function of a respective distance between the corresponding transistor and the boundary 408. Considering an acceptable characterization variation, n-type transistors and p-type transistors having unsatisfactory characterizations may be defined as dummy transistors and are not used for circuit functions, and n-type transistors and p-type transistors having acceptable characterizations may be defined as operational transistors and are used for circuit functions. In embodiments represented in FIG. 15, the semiconductor structure 400 includes a dummy device region 1000D having a number of dummy transistors. The dummy device region 1000D may span a width (i.e., W+W1+W2) (shown in FIG. 3A) along the X direction. For example, the dummy device region 1000D includes the gate stack 450M formed directly over the boundary 408, a number of n-type transistors (e.g., about two to five n-type transistors adjacent to the boundary 408) formed over the first device region 400N and a number of p-type transistors (e.g., about two to five p-type transistors adjacent to the boundary 408) formed over the second device region 400P. The semiconductor structure 400 includes an n-type operational device region 1000N that is adjacent to the dummy device region 1000D and includes n-type operational transistors formed over the first device region 400N. The semiconductor structure 400 also includes a p-type operational device region 1000P that is adjacent to the dummy device region 1000D on the other side and includes p-type operational transistors formed over the second device region 400P. The active region in the dummy device region may be referred to as dummy active region, and active region in the operational device regions may be referred to as operational or functional active region. The dummy active region aligns with and is in direct contact with the functional active region.

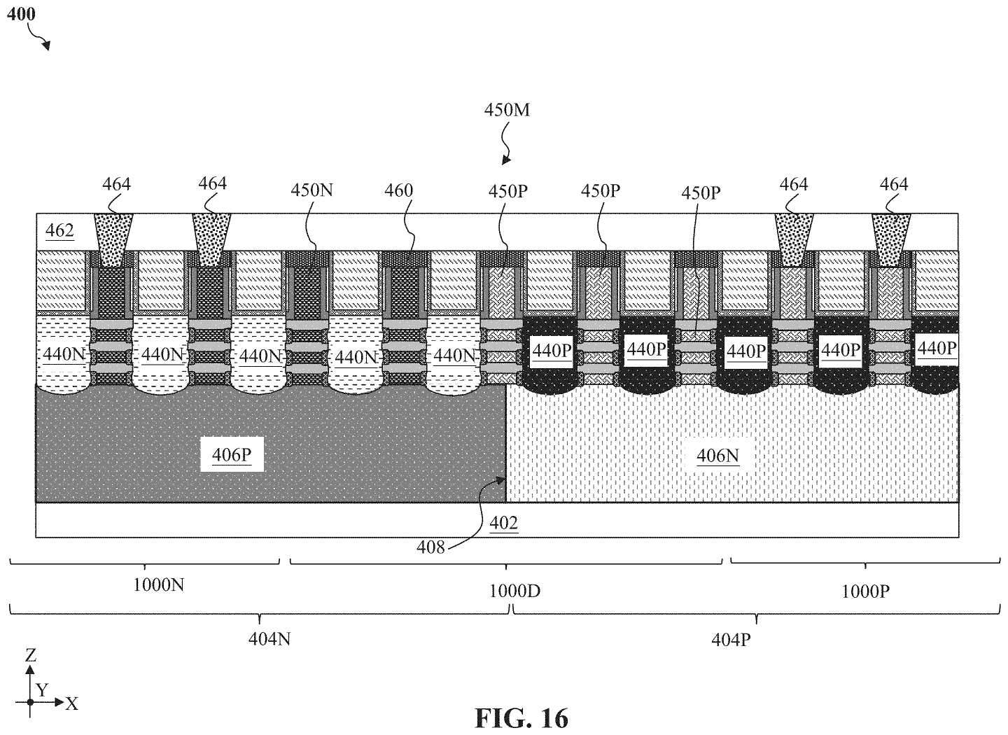

Referring to FIGS. 1 and 16, method 300 include a block 318 where further processes may be performed to complete the fabrication of the semiconductor structure 400. For example, such further processes may form self-aligned dielectric capping layer 460 over the gate stacks 450N and 450P (including the gate stack 450M) in the first device region 404N and second device region 404P, form various contacts/vias (e.g., gate contact vias 464), metal lines, power rails, as well as other multilayer interconnect features, such as ILD layers (e.g., ILD layer 462) and/or etch stop layer (ESLs) over the n-type operational device region 1000N and p-type operational device region 1000P of semiconductor structure 400, configured to connect the various features of the transistors in the n-type operational device region 1000N and p-type operational device region 1000P to form a functional circuit that includes the different semiconductor devices. That is, the contacts/vias, metal lines, and the power rails are formed to electrically connect with the operational transistors in the n-type operational device region 1000N and p-type operational device region 1000P. No contacts/vias, metal lines, or power rails would be formed to be electrically coupled to features of the dummy transistors in the dummy device region 1000D. Put differently, an interconnect structure formed over the workpiece 200 includes a functional portion that includes contact vias, metal lines, and/or or power rails over the n-type operational device region 1000N and p-type operational device region 1000P. The interconnect structure formed over the workpiece 200 includes a dummy portion that does not include contact vias, metal lines, or power rails.

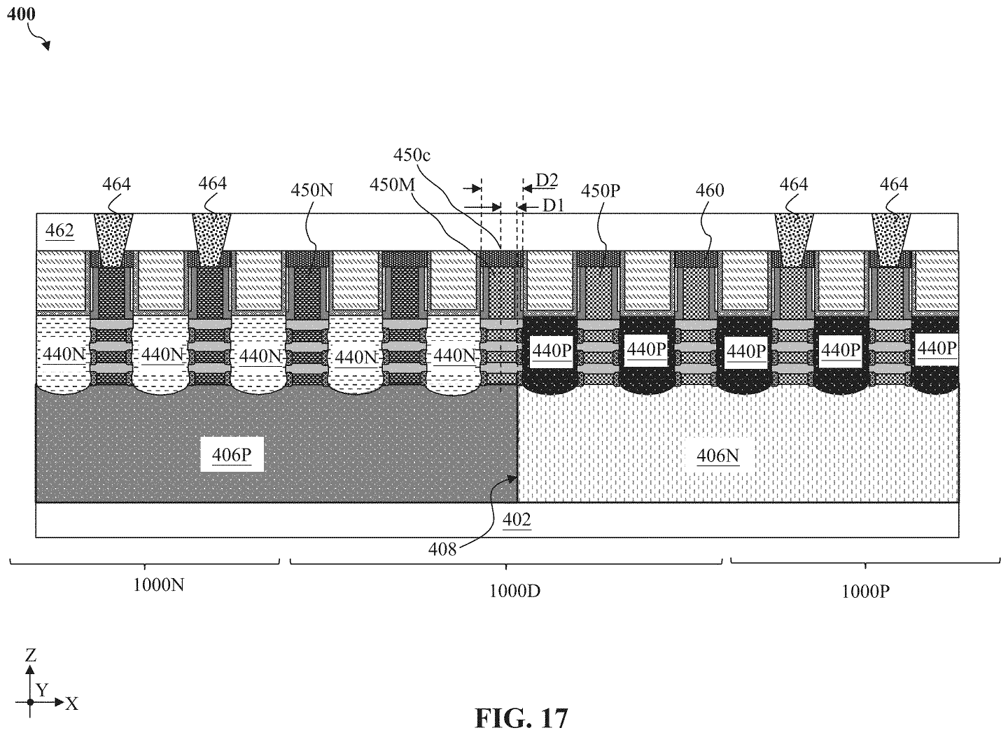

FIG. 17 depicts a cross-sectional view of a workpiece where there is an offset D1 between the center line 450c of the gate stack 450M and the boundary 408. The distance between two opposite gate spacers of the gate stack 450M is referred to as D2. A ratio of the offset D1 to D2 (i.e., D1/D2) may be less than 0.5 such that all the n-type epitaxial source/drain features 440N are formed over the first device region 404N and over the p well 406P, and all the p-type epitaxial source/drain features 440P are formed over the second device region 404P and over the n well 406N, and the transition between the n-type epitaxial source/drain feature 440N and the p-type epitaxial source/drain features 440P happens substantially at the gate stack 450M to substantially avoid anti-growth that may exist when the n-type epitaxial source/drain feature 440N and the p-type epitaxial source/drain feature 440P are formed right next each other.

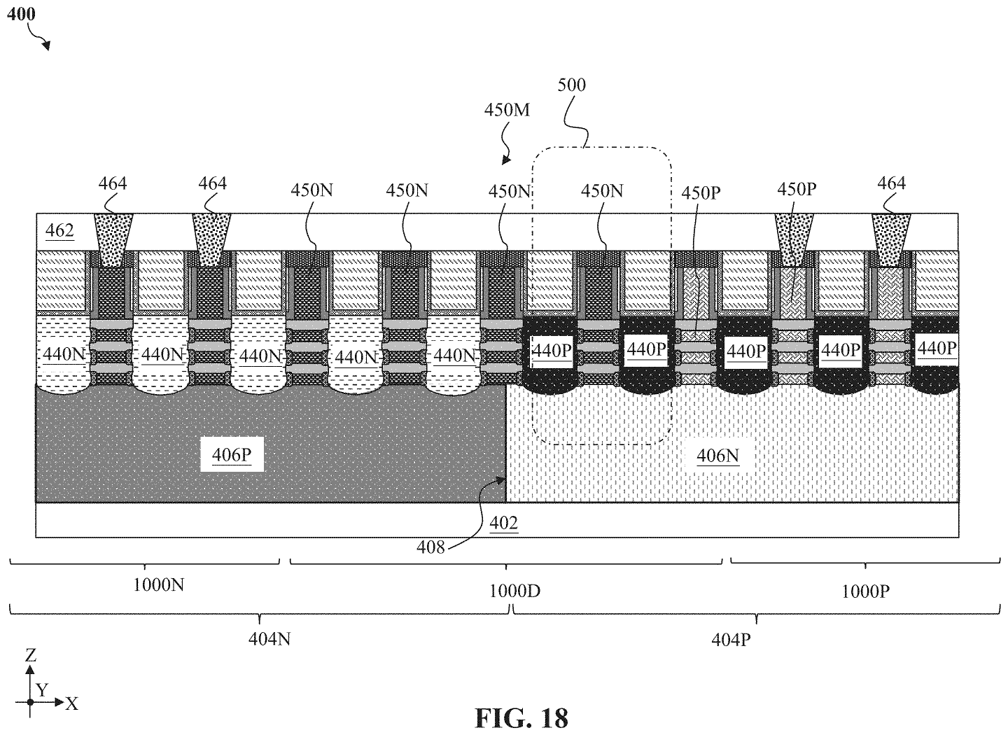

The threshold voltage of a transistor relates to the work function layer in the gate stack of the corresponding transistor. Forming n-type transistors with n-type work function layers and forming p-type transistors with p-type work function layers may provide the transistors corresponding satisfactory threshold voltages. FIG. 18 depicts an alternative embodiment where the dummy device region 1000D includes a dummy transistor 500 having p-type source/drain features 440P and a gate stack 450N disposed between the p-type source/drain features 440P. The gate stack 450N includes an n-type work function layer. By intentionally forming the p-type dummy transistor 500 with gate stack 450N, the n-type operational device region 1000N may be transitioned gradually to the p-type operational device region 1000P, leading to less defects. Considering the potential overlay associated with lithography processes, the dummy gate transistors close to the p-type operational device region 1000P would have gate stacks 450P, and dummy gate transistors close to the n-type operational device region 1000N would have gate stacks 450N. For example, in embodiments represented in FIG. 19, the dummy device region 1000D also includes a gate stack 450P disposed between the gate stack 450N and the p-type operational device region 1000P.

Based on the above descriptions, it can be seen that the present disclosure offers advantages over conventional methods and semiconductor structures. It is understood, however, that other embodiments may offer additional advantages, and not all advantages are necessarily disclosed herein, and that no particular advantage is required for all embodiments. For example, the present disclosure provides a semiconductor structure that includes an n-type transistor that is not isolated from an adjacent p-type transistor by any OD break features such as a shallow trench isolation feature. Instead, in embodiments of the present disclosure, the active region of n-type transistors aligns with and in direct contact with the active region of p-type transistors. That is, the active region is continuous for the n-type transistors and p-type transistors. By providing the continuous active region and ensuring the dummy gate stack disposed directly over the boundary of n well for forming p-type transistors and p well for forming n-type transistors, LOD effect may be avoided, the area wasted by the edge transistors may be substantially eliminated, and anti-growth of n-type epitaxial source/drain feature and p-type epitaxial source/drain feature may be avoided, leading to improved design flexibility and improved performance.

The present disclosure provides for many different embodiments. Semiconductor structures and methods of fabrication thereof are disclosed herein. In one exemplary aspect, the present disclosure is directed to a semiconductor structure. The semiconductor structure includes a substrate including a first well of a first conductivity type and a second well of a second conductivity type that is opposite of the first conductivity type, the first well abutting the second well along a boundary, the boundary extending lengthwise along a first direction. The semiconductor structure also includes a fin-shaped active region over the substrate and extending lengthwise along a second direction substantially perpendicular to the first direction, the fin-shaped active region extends across the boundary. The semiconductor structure also includes a first non-operational gate structure over the fin-shaped active region and extending lengthwise along the first direction, and the boundary is directly under the first non-operational gate structure.

In some embodiments, the semiconductor structure may also include a plurality of first source/drain features in the fin-shaped active region and the first well and a plurality of second source/drain features in the fin-shaped active region and the second well. The plurality of first source/drain features may be of the second conductivity type, and the plurality of second source/drain features may be of the first conductivity type. In some embodiments, the fin-shaped active region may include a channel region disposed directly under the first non-operational gate structure. The channel region may be disposed between and in direct contact with one of the plurality of first source/drain features and one of the plurality of second source/drain features. In some embodiments, the first conductivity type may include N type and the second conductivity type may include P type. In some embodiments, the first conductivity type may include P type and the second conductivity type may include N type. In some embodiments, the semiconductor structure may include a plurality of first gate stacks over the first well and having a first work function and a plurality of second gate stacks over the second well and having a second work function. The first work function may be different than the second work function. In some embodiments, the first non-operational gate structure may include the first work function. In some embodiments, the first non-operational gate structure may include the second work function. In some embodiments, the semiconductor structure may include a second non-operational gate structure disposed between the first non-operational gate structure and the plurality of first gate stacks and a third non-operational gate structure disposed between the first non-operational gate structure and the plurality of second gate stacks. The second non-operational gate structure comprises the first work function, and the third non-operational gate structure may include the second work function. In some embodiments, the fin-shaped active region may include a plurality of nanostructures over the substrate, and the first non-operational gate structure wraps around each of the plurality of nanostructures.

In another exemplary aspect, the present disclosure is directed to a semiconductor structure. The semiconductor structure includes a substrate including a first region abutting a second region along a boundary; a continuous active region over the substrate. The continuous active region includes a first operational active region over the first region, a second operational active region over the second region, and a dummy active region disposed between the first operational active region and the second operational active region. The semiconductor structure includes N-type transistors formed over the first region P-type transistors formed over the second region, and a dummy gate structure disposed over the dummy active region and between the N-type transistors and the P-type transistors. The dummy gate structure is disposed directly over the boundary.

In some embodiments, the semiconductor structure may also include one or more N-type dummy transistors over the first region and disposed between the dummy gate structure and the N-type transistors. The semiconductor structure may also include one or more P-type dummy transistors over the second region and disposed between the dummy gate structure and the P-type transistors. In some embodiments, the continuous active region may include a plurality of nanostructures. In some embodiments, the dummy gate structure may wrap around and over a portion of the plurality of nanostructures in the dummy active region. In some embodiments, the portion of the plurality of nanostructures may be in direct contact with an N-type source/drain feature over the first region and a P-type source/drain feature over the second region. In some embodiments, a center line of the dummy gate structure may be offset from the boundary.

In yet another exemplary aspect, the present disclosure is directed to a method. The method includes providing a substrate having an N well abutting a P well along a boundary, forming an active region over the substrate, the active region extending across the boundary, forming a first dielectric layer over the substrate and the active region, forming a first gate electrode over the first dielectric layer, patterning the first gate electrode and the first dielectric layer to form a plurality of gate structures such that a gate structure of the plurality of gate structures is disposed directly over the boundary, forming N-type source/drain features over the P well and P-type source/drain features over the N well, and replacing the plurality of gate structures with a plurality of gate stacks.

In some embodiments, the forming of the N-type source/drain features and P-type source/drain features may include recessing, by using the plurality of gate structures as an etch mask, the active region to form a plurality first trenches over the P well and a plurality second trenches over the N well, epitaxially form N-type source/drain features in the plurality first trenches, and epitaxially form P-type source/drain features in the plurality second trenches. The gate structure may be disposed between one of the N-type source/drain features and one of the P-type source/drain features. In some embodiments, the forming of the active region may include forming a vertical stack of alternating channel layers and sacrificial layers over the substrate and patterning the vertical stack and a portion of the substrate to form a fin-shaped active region. In some embodiments, the replacing of the plurality of gate structures may include performing a first etching process to remove the plurality of gate structures to form first plurality of openings, selectively removing the sacrificial layers to form second plurality of openings and forming the plurality of gate stacks in the first plurality of openings and the second plurality of openings. One of the gate stacks may be disposed directly over the boundary.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor structure, comprising:
a substrate including a first well of a first conductivity type and a second well of a second conductivity type that is opposite of the first conductivity type, wherein the first well abuts the second well along a boundary, the boundary extending lengthwise along a first direction;
a fin-shaped active region over the substrate and extending lengthwise along a second direction substantially perpendicular to the first direction, wherein the fin-shaped active region extends across the boundary; and
a first non-operational gate structure over the fin-shaped active region and extending lengthwise along the first direction, wherein the boundary is directly under the first non-operational gate structure.

2. The semiconductor structure of claim 1, further comprising:
a plurality of first source/drain features in the fin-shaped active region and the first well; and
a plurality of second source/drain features in the fin-shaped active region and the second well,
wherein the plurality of first source/drain features are of the second conductivity type, and
wherein the plurality of second source/drain features are of the first conductivity type.

3. The semiconductor structure of claim 2,
wherein the fin-shaped active region comprises a channel region disposed directly under the first non-operational gate structure,
wherein the channel region is disposed between and in direct contact with one of the plurality of first source/drain features and one of the plurality of second source/drain features.

4. The semiconductor structure of claim 2, wherein the first conductivity type comprises N type and the second conductivity type comprises P type.

5. The semiconductor structure of claim 2, wherein the first conductivity type comprises P type and the second conductivity type comprises N type.

6. The semiconductor structure of claim 1, further comprising:
a plurality of first gate stacks over the first well and having a first work function, and
a plurality of second gate stacks over the second well and having a second work function,
wherein the first work function is different than the second work function.

7. The semiconductor structure of claim 6, wherein the first non-operational gate structure comprises the first work function.

8. The semiconductor structure of claim 6, wherein the first non-operational gate structure comprises the second work function.

9. The semiconductor structure of claim 6, further comprising:
a second non-operational gate structure disposed between the first non-operational gate structure and the plurality of first gate stacks, and
a third non-operational gate structure disposed between the first non-operational gate structure and the plurality of second gate stacks,
wherein the second non-operational gate structure comprises the first work function, and the third non-operational gate structure comprises the second work function.

10. The semiconductor structure of claim 1,
wherein the fin-shaped active region comprises a plurality of nanostructures over the substrate, and
wherein the first non-operational gate structure wraps around each of the plurality of nano structures.

11. A semiconductor structure, comprising:
a substrate including a first region abutting a second region along a boundary;
a continuous active region over the substrate, the continuous active region comprising:
a first operational active region over the first region,
a second operational active region over the second region, and
a dummy active region disposed between the first operational active region and the second operational active region;
N-type transistors formed over the first region;
P-type transistors formed over the second region;
a dummy gate structure disposed over the dummy active region and between the N-type transistors and the P-type transistors,
wherein the dummy gate structure is disposed directly over the boundary.

12. The semiconductor structure of claim 11, further comprising:
one or more N-type dummy transistors over the first region and disposed between the dummy gate structure and the N-type transistors; and
one or more P-type dummy transistors over the second region and disposed between the dummy gate structure and the P-type transistors.

13. The semiconductor structure of claim 11, wherein the continuous active region comprises a plurality of nanostructures.

14. The semiconductor structure of claim 13, wherein the dummy gate structure wraps around and over a portion of the plurality of nanostructures in the dummy active region.

15. The semiconductor structure of claim 14, wherein the portion of the plurality of nanostructures is in direct contact with an N-type source/drain feature over the first region and a P-type source/drain feature over the second region.

16. The semiconductor structure of claim 11, wherein a center line of the dummy gate structure is offset from the boundary.

17. A method, comprising:
providing a substrate having an N well abutting a P well along a boundary;
forming an active region over the substrate, the active region extending across the boundary;
forming a first dielectric layer over the substrate and the active region;
forming a first gate electrode over the first dielectric layer;
patterning the first gate electrode and the first dielectric layer to form a plurality of gate structures such that a gate structure of the plurality of gate structures is disposed directly over the boundary;
forming N-type source/drain features over the P well and P-type source/drain features over the N well; and
replacing the plurality of gate structures with a plurality of gate stacks.

18. The method of claim 17, wherein the forming of the N-type source/drain features and P-type source/drain features comprises:
recessing, by using the plurality of gate structures as an etch mask, the active region to form a plurality first trenches over the P well and a plurality second trenches over the N well;
epitaxially form N-type source/drain features in the plurality first trenches; and
epitaxially form P-type source/drain features in the plurality second trenches,
wherein the gate structure is disposed between one of the N-type source/drain features and one of the P-type source/drain features.

19. The method of claim 17, wherein the forming of the active region comprises:
forming a vertical stack of alternating channel layers and sacrificial layers over the substrate; and
patterning the vertical stack and a portion of the substrate to form a fin-shaped active region.

20. The method of claim 19, wherein the replacing of the plurality of gate structures comprises:
performing a first etching process to remove the plurality of gate structures to form first plurality of openings;
selectively removing the sacrificial layers to form second plurality of openings; and
forming the plurality of gate stacks in the first plurality of openings and the second plurality of openings,
wherein on of the gate stacks is disposed directly over the boundary.
